(19) United States
(12) Patent Application Publication
(10) Pub. No.: US 2021/0305463 A1
(43) Pub. Date: Sep. 30, 2021

(54) OPTOELECTRONIC SEMICONDUCTOR COMPONENT AND METHOD FOR PRODUCING AN OPTOELECTRONIC SEMICONDUCTOR COMPONENT

(71) Applicant: OSRAM OLED GmbH, Regensburg (DE)

(72) Inventors: Martin BRANDL, Kelheim (DE); Luca HAIBERGER, Regensburg (DE)

(21) Appl. No.: 17/265,160

(22) PCT Filed: Aug. 21, 2019
(86) PCT No.: PCT/EP2019/072379

§ 371 Date: Feb. 1, 2021

(30) Foreign Application Priority Data
Aug. 31, 2018 (DE) 10 2018 121 334.4

(51) Int. Cl. H01L 33/46; H01L 25/16; H01L 33/50; H01L 33/56

(52) U.S. Cl. CPC H01L 33/46; H01L 25/167; H01L 33/50; H01L 2933/0025; H01L 2933/0041; H01L 2933/005; H01L 33/56

(57) ABSTRACT

An optoelectronic semiconductor component is specified having a semiconductor body comprising an active region provided for generating electromagnetic radiation, wherein the semiconductor body comprises a main surface which runs parallel to a main extension plane of the semiconductor body. Furthermore, the optoelectronic semiconductor component comprises a contact region, which is arranged on a side of the main surface facing away from the active region and is provided for making electrical contact with the semiconductor body, and a reflection layer, which is arranged on the side of the main surface facing away from the active region and reflects the electromagnetic radiation generated in the active region at least partially back in the direction of the active region. Further, a part of the main surface forms a radiation output coupling surface which is at least partially laterally limited by the reflection layer.

An optoelectronic semiconductor component and a method for producing an optoelectronic semiconductor component are specified. The optoelectronic semiconductor component is in particular a radiation-emitting optoelectronic semiconductor component which emits electromagnetic radiation, for example light, during operation.

One task to be solved is to specify an optoelectronic semiconductor component which comprises a radiation output coupling surface of a predetermined shape.

A further task to be solved is to specify a method for producing an optoelectronic semiconductor component which comprises a radiation output coupling surface of a predetermined shape.

According to at least one embodiment, the optoelectronic semiconductor component comprises a semiconductor body with an active region which is intended to generate electromagnetic radiation. The active region preferably comprises a pn junction, a double heterostructure, a single quantum well (SQW) or, particularly preferably, a multi quantum well (MQW) for radiation generation. The semiconductor body may also comprise further regions, which are in particular grown epitaxially on the semiconductor body. Furthermore, the semiconductor body comprises a main surface that runs parallel to a main extension plane of the semiconductor body.

According to at least one embodiment, the optoelectronic semiconductor component comprises a contact region which is arranged on a side of the main surface facing away from the active region and is provided for making electrical contact with the semiconductor body. The contact region is formed with an electrically conductive material and is preferably laterally adjacent to an edge of the main surface.

According to at least one embodiment, the optoelectronic semiconductor component comprises a reflection layer, which is arranged on the side of the main surface facing away from the active region and reflects the electromagnetic radiation generated in the active region at least partially back in the direction of the active region. The reflection layer is formed with a material which comprises a high reflection coefficient for the electromagnetic radiation generated in the active region. The electromagnetic radiation generated in the active region can therefore not completely penetrate the reflection layer.

According to at least one embodiment, a part of the main surface forms a radiation output coupling surface which is at least partially laterally limited by the reflection layer. In particular, the lateral direction extends parallel to the main extension plane of the semiconductor body. The radiation output coupling surface is the surface from which at least a part of the electromagnetic radiation generated in the active region is coupled out. The reflection layer limits the radiation output coupling surface at least partially. In other words, the reflection layer is directly adjacent to the radiation output coupling surface, at least in some regions. The shape and the area of the radiation output coupling surface can be easily adapted to given shapes and areas by an appropriately shaped reflection layer.

According to at least one embodiment, the contact region and the reflection layer are arranged side by side. Side by side means especially lateral side by side. The contact region and the reflection layer are at least partially arranged in a common plane.

According to at least one embodiment the optoelectronic semiconductor component comprises
a semiconductor body having an active region intended for generating electromagnetic radiation, wherein the semiconductor body comprises a main surface which is parallel to a main extension plane of the semiconductor body,
a contact region, which is arranged on a side of the main surface facing away from the active region and is provided for making electrical contact with the semiconductor body,
a reflection layer which is arranged on the side of the main surface facing away from the active region and reflects the electromagnetic radiation generated in the active region at least partially back in the direction of the active region, wherein
a part of the main surface forms a radiation output coupling surface,
the radiation output coupling surface is at least partially laterally limited by the reflection layer, and
the contact region and the reflection layer are arranged side by side.

An optoelectronic semiconductor component described herein is based on the following considerations, among others: In many applications it is desirable to design the shape of a radiation output coupling surface, for example, according to the specifications of an optically effective component. Both the shape and the surface area of the radiation output coupling surface can be important. Furthermore, it is advantageous to leave the structure and, in particular, the lateral expansions of the semiconductor body as unchanged as possible even with a modified radiation output coupling surface. Especially in mass production, a modification of the lateral expansion of the semiconductor body may require an adjustment of the manufacturing process and thus increase the manufacturing costs disadvantageously.

The optoelectronic semiconductor component described herein makes use, inter alia, of the idea to limit the lateral extent of the radiation output coupling surface arbitrarily by a reflection layer, which is laterally applied to the main surface of a semiconductor body. Electromagnetic radiation, which is emitted by the semiconductor component in the region of the reflection layer, can be reflected back into the semiconductor body by the reflection layer, scattered there, for example, and coupled out at another location of the radiation output coupling surface. Since the application of a reflection layer on the top layer of the semiconductor body does not touch the structure of the underlying semiconductor body, the radiation output coupling surface is thus advantageously simple and can be adapted to a corresponding specification within wide limits.

According to at least one embodiment of the optoelectronic semiconductor component, a lateral expansion of the reflection layer on the radiation output coupling surface corresponds to a lateral expansion of the contact region. The lateral extension of the reflection layer is preferably equal to the lateral extension of the contact region. A lateral expansion is in particular an edge length of an area limited by straight lines. The shape of the radiation output coupling surface, which results from an equal lateral expansion of the reflection layer and the contact region, is in particular a rectangular shape.

According to at least one embodiment of the optoelectronic semiconductor component, the reflection layer extends in lateral direction beyond an edge of the semiconductor body. If the reflection layer extends beyond the radiation output coupling surface of the semiconductor body, the requirement for an adjustment accuracy when applying the reflection layer is thus advantageously reduced. Furthermore, a lateral extension of the reflection layer can be larger than a lateral extension of the contact region.

According to at least one embodiment of the optoelectronic semiconductor component, the radiation output coupling surface comprises a rectangular, in particular square shape. By a suitable choice of the lateral extension of the reflection layer, the radiation output coupling surface can be rectangular and especially square. A square radiation output coupling surface can facilitate the attachment of subsequent optical components. In the case of a lens downstream of the semiconductor component, for example, a square shape of the radiation output coupling surface is advantageous for homogeneous radiation distribution after passing through the lens. In particular, the radiation output coupling surface can also be manufactured in many other shapes. For example, a circular, polygonal or other, for example composite, predetermined shape of the radiation output coupling surface can be produced.

According to at least one embodiment of the optoelectronic semiconductor component, a wavelength conversion layer is arranged between the reflection layer and the semiconductor body. The wavelength conversion layer converts at least a part of the electromagnetic radiation of a first wavelength impinging on it to an electromagnetic radiation of a second wavelength. In particular, the wavelength conversion layer is used to emit a mixed radiation, for example, to produce a white color impression in a viewer. The wavelength conversion layer can comprise a matrix material formed with silicone, epoxy resin or a ceramic in which scattering particles and a wavelength conversion material are preferably embedded. The scattering effect of the wavelength conversion layer can increase the output coupling efficiency of electromagnetic radiation reflected back from the reflection layer.

According to at least one embodiment of the optoelectronic semiconductor component, the reflection layer contains titanium dioxide. Titanium dioxide is characterized by an advantageously high reflectivity over a large spectral range, which in particular also includes the spectral range visible to humans. The reflection layer can also be formed with another highly reflective material, such as a metal or metal alloy. In particular, the reflection layer can be formed with silver. The reflection layer mainly comprises a high thermal resistance and a resistance to electromagnetic radiation generated in the active region during operation.

According to at least one embodiment of the optoelectronic semiconductor component, the reflection layer comprises a thickness in a range from at least 10 μm to at most 400 μm, preferably from at least 50 μm to at most 200 μm. The thickness designates a maximum expansion of the reflection layer in a direction parallel to a normal vector of the main extension plane of the reflection layer. A small thickness of the reflection layer is advantageous, since less space is required for the entire optoelectronic semiconductor component. In addition, a reflection layer that is too thick could complicate or prevent the contacting of the semiconductor body via the contact region. A reflection layer that is too thin, on the other hand, can already be partially transparent to the electromagnetic radiation that reaches it and allow undesired output coupling of the electromagnetic radiation.

According to at least one embodiment of the optoelectronic semiconductor component, a radiation-transmitting, preferably transparent or translucent encapsulation layer is arranged on the main surface of the semiconductor body. The encapsulation layer is formed, for example, with clear silicone and preferably comprises the same or a greater thickness than the reflection layer. The encapsulation layer causes a planarization of the surface of the optoelectronic semiconductor component and protects all underlying regions from external environmental influences and mechanical damage. Furthermore, the encapsulation layer can comprise a lens shape to improve the radiation extraction from the optoelectronic semiconductor component.

Furthermore, a method for producing an optoelectronic semiconductor component is specified. In particular, the method can be used to manufacture an optoelectronic semiconductor component described herein. This means that all features disclosed for the optoelectronic semiconductor component are also disclosed for the method and vice versa.

According to at least one embodiment of a method for producing an optoelectronic semiconductor component, the method comprises the following steps:

A) Providing a semiconductor body comprising an active region which is provided for generating electromagnetic radiation, wherein the semiconductor body comprises a main surface which runs parallel to the main extension plane of the semiconductor body, and a contact region which is arranged on a side of the main surface facing away from the active region and is provided for making electrical contact with the semiconductor body.

B) Arranging the semiconductor body on a substrate with a side opposite the main surface. The substrate is in particular a ceramic substrate and can be used both for mechanical stabilization of the optoelectronic semiconductor component and for efficient heat dissipation.

C) Applying a reflection layer on the side of the main surface facing away from the active region by spraying (jetting) or needle dosing, whereby part of the main surface forms a radiation output coupling surface. Furthermore, the radiation output coupling surface is at least partially laterally limited by the reflection layer, and the contact region and the reflection layer are arranged side by side.

According to at least one embodiment of the method for producing an optoelectronic semiconductor component, a wirebond process takes place between step B) and step C), in which the contact region is electrically conductively connected to a bonding wire. The bonding wire is preferably formed with a metal or a metal alloy and is intended for the electrical contacting of the optoelectronic semiconductor component.

According to at least one embodiment of the method for producing an optoelectronic semiconductor component, the reflection layer serves to reflect back the electromagnetic radiation generated in the active region in the direction of the active region. This results in an increased chance for the generated electromagnetic radiation to be coupled out from the radiation output coupling region.

According to at least one embodiment of the method for producing an optoelectronic semiconductor component, the semiconductor body is arranged with one side opposite to the main surface on the substrate by means of bonding, sintering or a eutectic soldering process.

According to at least one embodiment of the method for producing an optoelectronic semiconductor component, the method steps A, B and C are carried out successively in the order given here.

According to at least one embodiment of the method for producing an optoelectronic semiconductor component, a wavelength conversion layer is applied to the main surface of the semiconductor body between method step B) and method step C) by means of spray coating or layer transfer. The layer transfer process is preferred because it produces a smoother surface of the wavelength conversion layer. This facilitates the application of further layers on the wavelength conversion layer. Spray coating results in a higher surface roughness of the wavelength conversion layer, which can adversely affect the further arrangement of subsequent layers. The advantage of a process using spray coating is a shorter processing time compared to layer transfer.

According to at least one embodiment of the method for producing an optoelectronic semiconductor component, a radiation-transmitting, preferably transparent or translucent encapsulation layer is applied to the semiconductor body by means of a compression molding process. An encapsulation layer with clear silicone for example can be formed by compression molding. The clear silicone can also be filled with scattering particles or a wavelength conversion material.

According to at least one embodiment of the method for producing an optoelectronic semiconductor component, a limitation in a lateral direction is given for the radiation output coupling surface and a tool for the application of the reflection layer is moved laterally following a course of this limitation. For example, the reflection layer is applied with a needle dosing tool along an imaginary boundary line of the radiation output coupling surface on the main surface of the semiconductor body.

According to at least one embodiment of the method for producing an optoelectronic semiconductor component, the reflection layer is applied in such a way that a lateral expansion of the reflection layer is greater than a lateral expansion of the contact region. In particular, the reflection layer protrudes beyond the lateral boundary of the main surface of the semiconductor body. This reduces the requirement for a minimum expansion of the reflection layer.

Further advantages and advantageous embodiments and further developments of the optoelectronic semiconductor component result from the following exemplary embodiments shown in the figures.

Showing in:

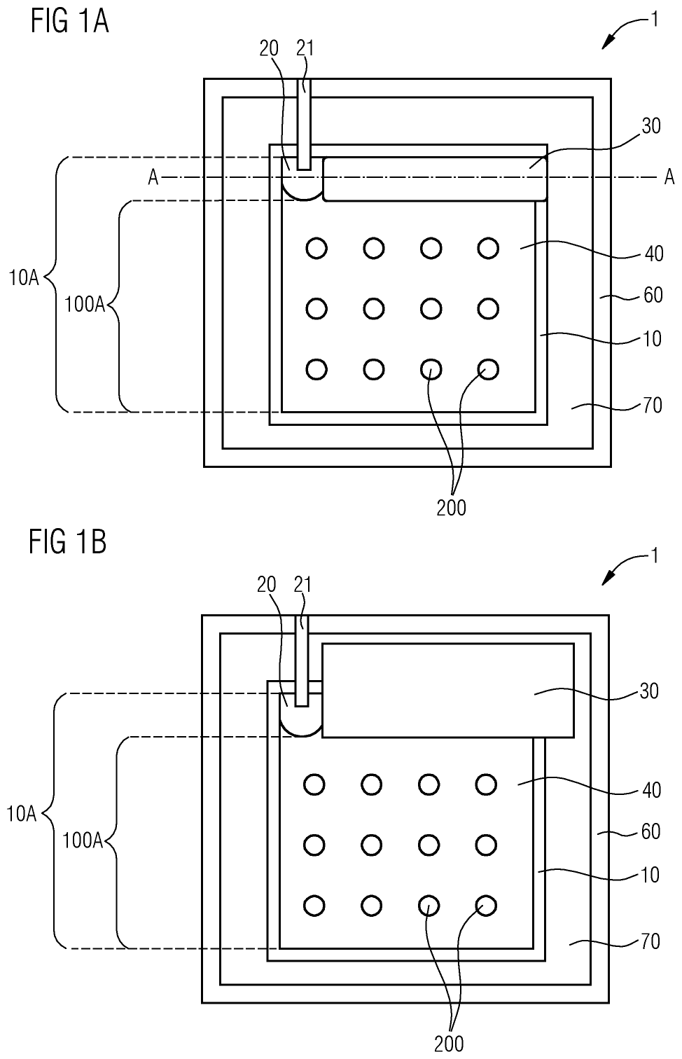

FIG. 1A a schematic top view of an optoelectronic semiconductor component described herein according to a first exemplary embodiment,

FIG. 1B a schematic top view of an optoelectronic semiconductor component described herein according to a second exemplary embodiment, and

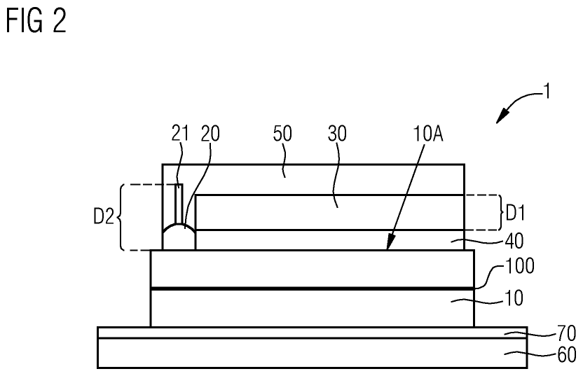

FIG. 2 a schematic cross-section of an optoelectronic semiconductor component described herein according to the first exemplary embodiment.

Identical, similar or similar-acting elements are marked with the same reference signs in the figures. The figures and the proportions of the elements shown in the figures are not to be regarded as true to scale. Rather, individual elements may be oversized for better representability and/or for better comprehensibility.

FIG. 1A shows a schematic top view of an optoelectronic semiconductor component 1 described herein according to a first exemplary embodiment. The optoelectronic semiconductor component 1 comprises a substrate 60 on which a semiconductor body 10 is arranged by means of a solder layer 70. The substrate 60 is a ceramic substrate, which comprises a high thermal conductivity and serves for the mechanical stabilization of the optoelectronic semiconductor component 1. The solder layer 70 is formed with a eutectic metal alloy, which enables a material connection between the substrate 60 and the semiconductor body 10.

The semiconductor body 10 comprises several epitaxially deposited layers of a semiconductor material, which include an active region 100 designed to generate electromagnetic radiation. Furthermore, the semiconductor body 10 comprises several vias 200 and a main surface 10A, which is arranged parallel to a main extension plane of the semiconductor body 10. The vias 200 provide electrical contact to a semiconductor layer of the semiconductor body 10.

On the side of the main surface 10A of the semiconductor body 10 facing away from the semiconductor body 10, a contact region 20 and a wavelength conversion layer 40 are arranged. The contact region 20 is intended for the electrical contacting of the semiconductor body 10 and is formed with a metal with good electrical conductivity. Preferably, the contact region 20 is formed with gold. The wavelength conversion layer 40 comprises a transparent matrix material in which a large number of wavelength conversion particles are embedded. The wavelength conversion particles can convert electromagnetic radiation of a first wavelength into electromagnetic radiation of a second wavelength.

Lateral to the contact region 20 a reflection layer 30 is arranged on top of the wavelength conversion layer 40. The main surface 10A is thus at least partially limited in its lateral extension by the reflection layer 30, so that a radiation output coupling surface 100A is formed. The reflection layer 30 is formed with titanium dioxide, which comprises a high degree of reflection over a large spectral range. At least part of the electromagnetic radiation emitted from the semiconductor body 10 is reflected by the reflection layer 30 back to the wavelength conversion layer 40. The reflection layer 30 is nontransmissive for the electromagnetic radiation emitted from the semiconductor body 10. The lateral expansion of the reflection layer 30 on the radiation output coupling surface 100A corresponds to the lateral expansion of the contact region 20. This results in a rectangular radiation output coupling surface 100A. At least a part of the electromagnetic radiation generated in the active region 100 is decoupled from the optoelectronic semiconductor component 1 by the radiation output coupling surface 100A.

FIG. 1B shows a schematic top view of an optoelectronic semiconductor component 1 described herein according to a second exemplary embodiment. The basic structure corresponds to the exemplary embodiment shown in FIG. 1A. In contrast, in the exemplary embodiment shown in FIG. 1B, the reflection layer 30 extends beyond the lateral boundaries of the semiconductor body 10 and protrudes above the semiconductor body 10. This means that a lower adjustment accuracy is required when the reflection layer 30 is applied, which facilitates the application of the reflection layer 30. Furthermore, the requirement for a minimum width of the reflection layer 30 is advantageously reduced. In other words, a reflection layer 30 that comprises a larger lateral extension than the contact region 20 can also be used.

FIG. 2 shows a schematic cross-section through an optoelectronic semiconductor component 1 described herein along the cutting line A shown in FIG 1A according to the first exemplary embodiment. The semiconductor body 10 comprises an active region 100 and is mounted with its side facing away from the main surface 10A on a substrate 60. On the main surface 10A of the semiconductor body 10 a wavelength conversion layer 40 is arranged. The wavelength conversion layer 40 is followed by a reflection layer 30, which comprises a thickness D1. The thickness D1 of the reflection layer 30 is the maximum expansion in the direction parallel to a normal vector of the main extension plane of the reflection layer 30.

Laterally adjacent to the reflection layer 30 a contact region 20 is arranged. The contact region 20 is formed with a metal or a metal alloy and arranged on the main surface 10A of the semiconductor body. The contact region 20 forms an ohmic contact to the semiconductor body 10 and is configured to energize the semiconductor body 10. The reflection layer 30 and the contact region 20 are completely covered by an encapsulation layer 50. The encapsulation layer 50 is formed with a transparent silicone and serves mainly for the mechanical stabilization of a bonding wire 21, which is arranged on the contact region 20. The bonding wire 21 is formed with gold and is applied to the contact region 20 by a wirebond process. The contact region 20 is energized by the bonding wire 21. The thickness D1 of the reflection layer 30 is less than or equal to the thickness D2 of the contact region 20 and of the bonding wire 21 applied to it. Thus, the total thickness of the optoelectronic semiconductor component 1 is advantageously not increased by the reflection layer 30. The thickness D2 of the contact region 20 and of the bonding wire 21 is considered to be the maximum extension of the contact region 20 and of the bonding wire 21 in the direction parallel to a normal vector of the main extension plane of the contact region 20. The reflection layer 30 contains titanium dioxide and comprises a high reflectivity for the electromagnetic radiation generated in the active region 100.

The invention is not limited by the description based on the exemplary embodiments. Rather, the invention comprises each new feature as well as each combination of features, which in particular includes each combination of features in the claims, even if this feature or combination itself is not explicitly specified in the claims or exemplary embodiments.

This patent application claims the priority of the German patent application 102018121334.4, the disclosure content of which is hereby included by reference.

### LIST OF REFERENCE SIGNS

1 optoelectronic semiconductor component

10 semiconductor body

20 contact region

21 bonding wire

30 reflection layer

40 wavelength conversion layer

50 encapsulation layer

60 substrate

70 solder layer

100 active region

200 vias

10A main surface

100A radiation output coupling surface

A cutting line

D1 thickness of the reflection layer

D2 thickness of the contact region and bonding wire

1. An optoelectronic semiconductor component with
a semiconductor body having an active region provided for generating electromagnetic radiation, wherein the semiconductor body comprises a main surface which is parallel to a main extension plane of the semiconductor body,
a contact region, which is arranged on a side of the main surface facing away from the active region and is provided for making electrical contact with the semiconductor body
a reflection layer which is arranged on the side of the main surface facing away from the active region and reflects the electromagnetic radiation generated in the active region at least partially back in the direction of the active region, wherein
a part of the main surface forms a radiation output coupling surface
the radiation output coupling surface is at least partially laterally limited by the reflection layer,
the contact region and the reflection layer are arranged side by side, and
a lateral expansion of the reflection layer on the radiation output coupling surface corresponds to a lateral expansion of the contact region.

2. The optoelectronic semiconductor component according to claim 1, in which the reflection layer extends in the lateral direction beyond an edge of the semiconductor body.

3. The optoelectronic semiconductor component according to claim 1, in which the radiation output coupling surface comprises a rectangular, in particular square shape.

4. The optoelectronic semiconductor component according to claim 1, in which a wavelength conversion layer is arranged between the reflection layer and the semiconductor body.

5. The optoelectronic semiconductor component according to claim 1, in which the reflection layer comprises titanium dioxide.

6. The optoelectronic semiconductor component according to claim 1, in which the reflection layer comprises a thickness in a range from at least 10 μm to at most 400 μm, preferably from at least 50 μm to at most 200 μm.

7. The optoelectronic semiconductor component according to claim 1, in which a radiation-transmitting, preferably transparent or translucent encapsulation layer is arranged on the main surface of the semiconductor body.

8. A method for producing an optoelectronic semiconductor component comprising the following steps:
A) providing a semiconductor body comprising an active region which is provided for generating electromagnetic radiation, wherein the semiconductor body has a main surface which runs parallel to the main extension plane of the semiconductor body, and a contact region which is arranged on a side of the main surface facing away from the active region and is provided for making electrical contact with the semiconductor body,
B) Arranging the semiconductor body on a substrate with one side opposite the main surface,
C) Application of a reflection layer on the side of the main surface facing away from the active region by means of spraying or needle dosing, wherein part of the main surface forms a radiation output coupling surface, the radiation output coupling surface is at least partially laterally limited by the reflection layer, and the contact region and the reflection layer are arranged side by side.

9. The method for producing an optoelectronic semiconductor component according to claim 8, wherein the semiconductor body is arranged on a substrate with a side opposite the main surface by means of bonding, sintering or a eutectic soldering process.

10. The method for producing an optoelectronic semiconductor component according to claim 8, wherein the method steps are carried out in the order given.

11. The method for producing an optoelectronic semiconductor component according to claim 8, wherein, between method step B) and method step C), a wavelength conversion layer is applied to the main surface of the semiconductor body by means of spray coating or layer transfer.

12. The method for producing an optoelectronic semiconductor component according to claim 8, wherein a radiation-transmitting, preferably transparent or translucent encapsulation layer is applied to the semiconductor body by means of a compression molding method.

13. The method for producing an optoelectronic semiconductor component according to claim 8, wherein a boundary in a lateral direction is predetermined for the radiation output coupling surface, and a tool for applying the reflection layer is moved laterally following a course of the boundary.

14. The method for producing an optoelectronic semiconductor component according to claim 8, wherein the reflection layer is applied in such a way that a lateral extent of the reflection layer is greater than a lateral extent of the contact region.

15. The method for producing an optoelectronic semiconductor component according to claim 8, wherein a lateral expansion of the reflection layer on the radiation output coupling surface corresponds to a lateral expansion of the contact region.
